(19) United States
(12) Patent Application Publication
(10) Pub. No.: US 2012/0208481 A1
(43) Pub. Date: Aug. 16, 2012

(54) REMOTELY CONTROLLING SOUND SYSTEM IN ENCLOSURE

(75) Inventor: Amar G. Bose, Wayland, MA (US)

(73) Assignee: Bose Corporation

(21) Appl. No.: 13/454,722

(22) Filed: Apr. 24, 2012

Related U.S. Application Data
(63) Continuation of application No. 10/844,700, filed on May 13, 2004, now abandoned.

(51) Int. Cl. H04B 1/18; H05K 11/00

(52) U.S. Cl. 455/151.2; 455/344

(57) ABSTRACT

A sound reproducing system having at least a radio and left and right loudspeakers in a base enclosure is free of at least manually selectable volume controlling and radio tuning A remote controller includes at least manually selectable volume and tuning controls.

The present invention relates in general to remotely controlling sound reproduction and more particularly concerns apparatus and techniques for remotely controlling a sound system in an enclosure that includes at least a radio and may also include a CD player with the enclosure preferably free of all manual selectors and at least free of volume control selectors, tuning selectors, CD play/pause selectors and CD track selectors.

### BACKGROUND OF THE INVENTION

For background, reference is made to the commercially available Bose® Wave® radio/CD incorporated herein by reference.

### SUMMARY OF THE INVENTION

According to the invention, a sound reproducer has a base enclosure that includes left and right loudspeakers and a radio. The base enclosure is free of at least manually selectable controls for volume and station tuning An embodiment also having a CD player in the base enclosure is also free of at least manually selectable play/pause controls, stop/eject controls, and track controls. There is a remote controller that has all manually selectable controls for controlling the reproduced sound from the base enclosure, typically an infrared remote control. Preferably, the base enclosure is free of all manually selectable controls.

Numerous other features, objects and advantages will be come apparent from the following detailed description when read in connection with the accompanying drawing in which:

### BRIEF DESCRIPTION OF THE SEVERAL VIEWS OF THE DRAWING

FIG. 1 is a perspective view of the commercially available Bose® Wave® radio/CD;

FIG. 2 is a perspective view of a radio/CD according to the invention that is free of all manually selectable controls; and

FIG. 3 is a plan view of a remote control for remotely controlling all the functions of the radio/CD of FIG. 2.

### DETAILED DESCRIPTION

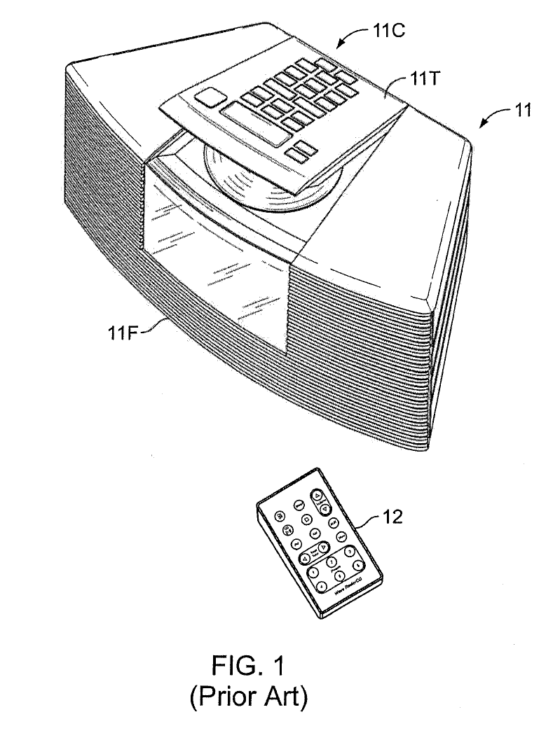

With reference now to the drawing and more particularly FIG. 1 thereof, there is shown a perspective view of a commercially available Bose® Wave® radio/CD comprising a base enclosure 11 having a clock radio and CD player with left and right loudspeakers behind the front grill 11F. There are a number of manually selectable controls 11C on the top panel 11T that are duplicated on remote control 12.

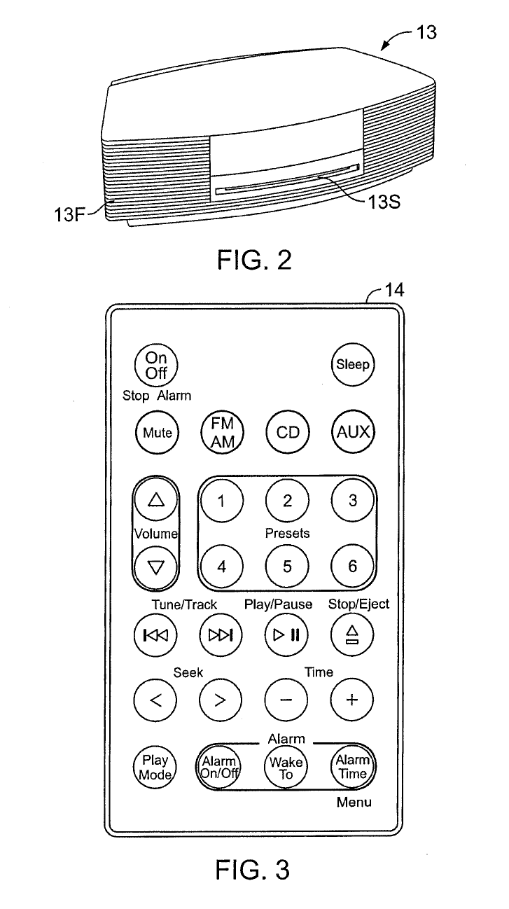

Referring to FIG. 2, there is shown a perspective view of a clock radio/CD base enclosure 13 according to the invention that is entirely free of manually selectable controls. This embodiment also includes a CD player having a slot 13S on the front panel 13F for receiving and ejecting CD's. There are left and right loudspeakers behind front grill 13F, preferably comprising acoustic waveguide loudspeaker systems.

Referring to FIG. 3, there is shown a plan view of a remote control for controlling the radio/CD of FIG. 2. Remote control 14 includes 26 pressure-sensitive switches labeled according to their functions. Play mode functions to select shuffle and repeat CD play modes. Alarm on/off switch turns the alarm on or off. Wake to switch sets playing the radio or CD as an alarm. The alarm time switch enters the alarm time setup mode when pressed once and enters the system setup menu when pressed and held for at least a second. The time − and + switches set clock time and in the alarm set mode set alarm time. The seek switches find the next radio station with a strong signal.

The tune/track switches skip to the next/previous stored radio frequency or skip to the next/previous CD track. The play/pause switch plays a CD or pauses a playing CD. The stop/eject switch stops a playing CD when pressed once and ejects a stopped CD when pressed again. The presets store a radio station for quick recall when pressed and held and recall a stored radio location when pressed after storage. The mute switch silences audio when pressed and restores audio when pressed again. The FM/AM switch turns the radio on and switches between FM and AM when pressed again. The CD switch turns the CD player on. The AUX switch causes audio from an external source to be heard when pressed. The On/Off switch turns the power on or off and stops a sounding alarm. The sleep switch snoozes a sounding alarm and sets the unit to shut off automatically after a predetermined number of minutes.

The invention is embodied in the Bose® Wave® Radio/CD II commercially available shortly after the filing date of this application.

An important object of the invention is to motivate users of the radio/CD to listen to the sound reproducing system at a distance from the base enclosure where it is believed the perceived sound quality is better than when the user is closely adjacent to the base enclosure.

It is evident that those skilled in the art may now make numerous uses and modifications of and departures from the apparatus and techniques herein disclosed without departing from the inventive concepts. Consequently, the invention is to be construed as embracing each and every novel feature and novel combination of features present or possessed by the apparatus and technique herein disclosed and limited solely by the spirit and scope of the appended claims.

What is claimed is:

1.-5. (canceled)

6. A tabletop music system with a clock radio comprising:
a base enclosure comprising a top surface and a front surface;
a source of audio electrical signals comprising a radio receiver located within the base enclosure for receiving radio signals;
at least one speaker located within the base enclosure for producing audio in response to the audio electrical signal;
a clock located on the front surface of the base enclosure for displaying at least time;
an alarm configured to be set by a user to produce an audible alarm;
wherein the base enclosure is free of selectable mechanical controls that permit the user to set an alarm time.

7. The tabletop music system of claim 6 wherein the radio receiver comprises an FM radio receiver.

8. The tabletop music system of claim 7 wherein the radio receiver further comprises an AM radio receiver.

9. The tabletop music system of claim 6 further comprising an acoustic waveguide in the base enclosure and acoustically coupled to the speakers.

10. The tabletop music system of claim 6 further comprising a CD player in the base enclosure.

11. The tabletop music system of claim 10 wherein the CD player includes a slot on the front surface of the base for receiving and ejecting CDs.

12. The tabletop music system of claim 6 further comprising a wireless remote control device configured to enable a user to set an alarm time.

13. The tabletop music system of claim 12 wherein the wireless remote control device comprises a pressure-sensitive mode switch for controlling a first function and a second function.

14. The tabletop music system of claim 12 wherein the wireless remote control device comprises one or more buttons that permits the user to set the time.

15. The table top music system of claim 12 wherein the wireless remote control device comprises one or more buttons that permits the user to select a source of audio electrical signals.

16. The table top music system of claim 12 wherein the wireless remote control device comprises one or more buttons that permits the user to store and recall preset radio stations.

17. The tabletop music system of claim 6, wherein the base enclosure is devoid of any manually selectable mechanical controls on its front and top surfaces.

18. The tabletop music system of claim 6, wherein the base enclosure is devoid of any manually selectable mechanical controls on all surfaces.

19. A table top music system comprising:
an base enclosure comprising a top surface a front surface;
a display located on the front surface for displaying at least time;
at least one loudspeaker located within the base enclosure for reproducing audio from an audio source;
an alarm configured to be set by a user to produce an audible alarm; and
wherein the base enclosure is devoid of manually-selectable mechanical controls.

20. The tabletop music system of claim 19, further comprising:
a wireless remote control configured to control various functions of the tabletop music system, the functions including at least setting the alarm.

21. The tabletop music system of claim 19, wherein the tabletop music system further comprises an audio source within the base enclosure.

22. The tabletop music system of claim 21, wherein the audio source comprises a radio receiver.

23. The tabletop music system of claim 19, wherein the tabletop music system comprises a plurality of audio sources within the base enclosure.

24. The tabletop music system of claim 23, wherein the plurality of music sources comprises at least a radio receiver and a CD player.

25. A tabletop music system comprising:
a base enclosure comprising a top surface, a bottom surface, a front surface, a rear surface, a left surface and a right surface;
a clock located on the front surface of the base enclosure for displaying at least time;
a radio receiver located within the base enclosure, wherein the radio receiver is configured to produce audio electrical signals from received radio signals;
a plurality of speakers for producing audio from the audio electrical signals produced by the radio receiver;
an alarm configured to be set by a user to produce an audible alarm;
a remote control configured to wirelessly communicate with the base enclosure to control a plurality of functions of the base enclosure; and
wherein at least the top surface, front surface, left surface and right surface of the enclosure are devoid of manually selectable mechanical controls.

26. The tabletop music system of claim 25, wherein the rear surface and bottom surface are devoid of manually selectable mechanical controls.

27. The tabletop music system of claim 25, wherein the remote control controls all of the user-controllable functions of the base enclosure.

28. The tabletop music system of claim 25 further comprising an acoustic waveguide located within the enclosure and acoustically coupled to at least one of the plurality of speakers.
